(19) United States
(12) Patent Application Publication
(10) Pub. No.: US 2003/0015796 A1
(43) Pub. Date: Jan. 23, 2003

(54) Semiconductor device and production method thereof

(75) Inventor: Eiji Hasunuma, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/145,199

(22) Filed: May 15, 2002

(30) Foreign Application Priority Data
Jul. 18, 2001 (JP) 2001-217847 (P)

(51) Int. Cl. H01L 23/48

(52) U.S. Cl. 257/758

(57) ABSTRACT

Tilted wall member having a tilted wall for gradually reducing the aperture width of contact hole in a downward direction is disposed on a part of an inner wall surface of contact hole in this semiconductor device. This tilted wall member is disposed between first interlayer dielectric film and second interlayer dielectric film, and contact hole is disposed so that the aperture width at the lower end may be smaller than the aperture width at the upper end. This reduces the aperture width on the lower end side of the contact hole without reducing the aperture width on the upper end side of the contact hole, so that the overlap shift margin (tolerance) between the contact hole and the bitline can have an enlarged range.

### BACKGROUND OF THE INVENTION

1. Field of the Invention

The present invention relates to a semiconductor device and a production method thereof, and more particularly to a semiconductor device having a contact hole and a production method thereof.

2. Description of the Background Art

Hereafter, with the use of FIGS. 28 to 32, a method of producing a contact hole formed in a general DRAM will be described. First, referring to FIG. 28, a silicon dielectric film 11 is formed on a semiconductor substrate 10, and a silicon film 12 is formed on this silicon dielectric film 11.

Silicon dielectric film 11 is constructed with a dielectric film such as TEOS oxide film or nitride film deposited by the reduced-pressure CVD (chemical vapor deposition) method or the ordinary-pressure CVD method, or with a laminate film thereof. Silicon dielectric film 11 has a film thickness of from about 50 nm to about 1000 nm.

Silicon film 12 is constructed with polycrystalline silicon, amorphous silicon, or the like formed by the CVD method and doped with an impurity such as P or As, a silicide film of a high-melting-point metal film such as Ti, TiN, or W, or a laminate film thereof, or an electrically conductive metal film such as W or Al. Silicon film 12 has a film thickness of from about 50 nm to 500 nm.

Next, referring to FIG. 29, with the use of a photoresist having a predetermined pattern as a mask, a bitline 12 having a predetermined shape is formed by means of dry etching such as the RIE method. Thereafter, a silicon dielectric film 13 is formed to cover bitline 12. Subsequently, a storage node contact (not illustrated) and a storage node (not illustrated) are formed, and a silicon film 14 is formed on silicon dielectric film 13.

Silicon dielectric film 13 is a dielectric film such as TEOS oxide film deposited by the reduced-pressure CVD method or the ordinary-pressure CVD method, and has a film thickness of from about 100 nm to about 300 nm. Silicon film 14 is a film constructed with polycrystalline silicon or amorphous silicon deposited by the CVD method and doped with an impurity such as P or As, a silicide film of a high-melting-point metal film such as Ti, TiN, or W, or a laminate film thereof, or an electrically conductive metal film such as W or Al, and has a film thickness of from about 150 nm to 500 nm.

Next, referring to FIG. 30, with the use of a photoresist having a predetermined pattern as a mask, a cell plate 14 having a predetermined shape is formed by means of dry etching such as the RIE method. Thereafter, a silicon dielectric film 15 is formed. Silicon dielectric film 15 is a dielectric film such as TEOS oxide film deposited by the reduced-pressure CVD method or the ordinary pressure CVD method, and has a film thickness of from about 100 nm to 3000 nm.

Next, referring to FIG. 31, a resist film 16 having an opening above bitline 12 is formed on silicon dielectric film 15. Thereafter, with the use of this resist film 16 as a mask, a contact hole 21 that extends to bitline 12 is opened by means of dry etching such as the RIE method.

Next, referring to FIG. 32, after resist film 16 is removed, a contact plug 22 is formed within contact hole 21. Thereafter, an upper wiring layer 23 electrically connected to contact plug 22 is formed on silicon dielectric film 15.

In the above-mentioned method of producing a contact hole formed in a conventional DRAM, bitline 12 is formed to have a width (W1 in FIG. 32) of from about 0.2 μm to about 1.0 μm, and contact hole 21 is formed to have an aperture width (W2 in FIG. 32) of from about 0.2 μm to about 0.5 μm, as shown in FIG. 32. As a result of this, the overlap shift margin (tolerance) between bitline 12 and contact hole 21 is small, and hence the pitch of bitline 12 cannot be reduced.

Here, it is difficult to form a contact hole 21 having a reduced aperture width from the upper end side down to the lower end side, because it is difficult to form a photomask having an aperture width smaller than the aforesaid aperture width, due to limited resolution provided by the photolithography technique.

### SUMMARY OF THE INVENTION

The present invention has been made in order to solve the aforementioned problems of the prior art, and an object thereof is to reduce the aperture width on the lower end side of the contact hole without reducing the aperture width on the upper end side of the contact hole so that the overlap shift margin (tolerance) between the contact hole and the bitline can have an enlarged range.

A semiconductor device according to the present invention includes a lower wiring layer, an interlayer dielectric film disposed on the lower wiring layer, an upper wiring layer disposed on the interlayer dielectric film, a contact hole disposed through the interlayer dielectric film to couple the lower wiring layer and the upper wiring layer with each other, and a contact plug buried in the contact hole to establish an electrical connection between the lower wiring layer and the upper wiring layer, wherein a tilted wall member is disposed on an inner wall surface of the contact hole for gradually reducing an aperture width of the contact hole in a downward direction.

A method of producing a semiconductor device according to one aspect of the present invention includes the steps of forming a lower wiring layer, forming a first interlayer dielectric film on the lower wiring layer, forming an etching control member having a predetermined shape on the first interlayer dielectric film, forming a second interlayer dielectric film on the first interlayer dielectric film and the etching control member, forming a contact hole by etching so that the contact hole may pass the etching control member to reach the lower wiring layer, forming a contact plug in the contact hole so that the contact plug may be electrically connected to the lower wiring layer, and forming an upper wiring layer on the second interlayer dielectric film so that the upper wiring layer may be electrically connected to the contact plug, wherein the etching control member is made of a material having a lower etching rate than the second interlayer dielectric film with respect to an etchant used in forming the contact hole.

A method of producing a semiconductor device according to another aspect of the present invention includes the steps of forming a lower wiring layer, forming an etching control member on the lower wiring layer, forming an interlayer dielectric film on the etching control member, forming a contact hole by etching so that the contact hole may pass the etching control member to reach the lower wiring layer, forming a contact plug in the contact hole so that the contact plug may be electrically connected to the lower wiring layer, and forming an upper wiring layer on the interlayer dielectric film so that the upper wiring layer may be electrically connected to the contact plug, wherein the etching control member is made of a material having a lower etching rate than the interlayer dielectric film with respect to an etchant used in forming the contact hole.

According to the aforesaid semiconductor device and production method thereof, by providing a tilted wall member made of an etching control member, one can reduce the aperture width of the contact hole located below the etching control member. As a result of this, one can form a contact hole having an aperture width smaller than the resolution limit of the photomask technique, whereby the overlap margin between the contact hole and the lower wiring layer can be increased.

In the aforesaid semiconductor device, the interlayer dielectric film preferably has a first interlayer dielectric film located on a lower side and a second interlayer dielectric film disposed above the first interlayer dielectric film, and the tilted wall member is preferably disposed between the first interlayer dielectric film and the second interlayer dielectric film.

Further, in the aforesaid semiconductor device and production method, the contact hole is preferably disposed to penetrate through the tilted wall member. By this construction, a tilted wall having a funnel shape is formed in the tilted wall member, whereby the aperture width on the lower end side of the contact hole can be further reduced.

Further, in the aforesaid semiconductor device, the tilted wall member is preferably a dummy cell plate electrode. The tilted wall member is more preferably disposed between the interlayer dielectric film and the lower wiring layer.

Further, the aforesaid method of producing a semiconductor device preferably further includes the step of forming a cell plate electrode between the first interlayer dielectric film and the second interlayer dielectric film, and the step of forming the etching control member is carried out so that the etching control member may be formed in the same step and with the same material as in the step of forming the cell plate electrode. By this construction, the etching control member can be formed simultaneously with the step of forming the cell plate electrode, whereby the production process is simplified.

Further, the aforesaid method of producing a semiconductor device preferably includes the steps of forming a lower wiring layer, forming an etching control member on the lower wiring layer, forming an interlayer dielectric film on the etching control member, forming a contact hole by etching so that the contact hole may pass the etching control member to reach the lower wiring layer, forming a contact plug in the contact hole so that the contact plug may be electrically connected to the lower wiring layer, and forming an upper wiring layer on the interlayer dielectric film so that the upper wiring layer may be electrically connected to the contact plug, wherein the etching control member is made of a material having a lower etching rate than the interlayer dielectric film with respect to an etchant used in forming the contact hole.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a structure of a semiconductor device in a first embodiment;

FIGS. 2 to 5 are cross-sectional views respectively illustrating the first to fourth steps in a method of producing the semiconductor device in the first embodiment;

FIG. 6 is a cross-sectional view illustrating a structure of a semiconductor device in a second embodiment;

FIGS. 7 to 10 are cross-sectional views respectively illustrating the first to fourth steps in a method of producing the semiconductor device in the second embodiment;

FIG. 11 is a cross-sectional view illustrating a structure of a semiconductor device in a third embodiment;

FIGS. 12 to 14 are cross-sectional views respectively illustrating the second to fourth steps in a method of producing the semiconductor device in the third embodiment;

FIG. 15 is a cross-sectional view illustrating a structure of a semiconductor device in a fourth embodiment;

FIGS. 16 to 18 are cross-sectional views respectively illustrating the second to fourth steps in a method of producing the semiconductor device in the fourth embodiment;

FIG. 19 is a cross-sectional view illustrating a structure of a semiconductor device in a fifth embodiment;

FIGS. 20 to 23 are cross-sectional views respectively illustrating the first to fourth steps in a method of producing the semiconductor device in the fifth embodiment;

FIG. 24 is a cross-sectional view illustrating a structure of a semiconductor device in a sixth embodiment;

FIGS. 25 to 27 are cross-sectional views respectively illustrating the first to third steps in a method of producing the semiconductor device in the sixth embodiment; and

FIGS. 28 to 32 are cross-sectional views respectively illustrating the first to final steps in a method of producing a semiconductor device according to a prior art.

### DESCRIPTION OF THE PREFERRED EMBODIMENTS

Hereafter, embodiments of semiconductor devices and methods of producing the same according to the present invention will be described with reference to the attached drawings. Here, in the semiconductor device described below, a connection structure between a contact hole and a bitline formed on a general DRAM is described in order to show the characteristic features of the present invention clearly; however, the present invention can be applied to a connection structure between a contact hole and a gate electrode and to a connection structure between a contact hole and a substrate as well.

(First Embodiment)

Hereafter, referring to FIGS. 1 to 5, a semiconductor device and a method of producing the same according to a first embodiment will be described.

First, referring to FIG. 1, the structure of a semiconductor device according to this embodiment will be described. A silicon dielectric film 11 is disposed on a semiconductor substrate 10. A silicon film 12 having a predetermined shape and constituting a lower wiring layer is disposed on this silicon dielectric film 11. A first interlayer dielectric film 13 is disposed to cover silicon dielectric film 11 and silicon film 12, and further a second interlayer dielectric film 15 is disposed on this first interlayer dielectric film 13.

A contact hole 21 that extends to silicon film 12 is disposed through first interlayer dielectric film 13 and second interlayer dielectric film 15. With regard to this contact hole 21, a tilted wall member 51 having a tilted wall 21a for gradually reducing the aperture width of contact hole 21 in a downward direction is disposed on a part of an inner wall surface of contact hole 21. This tilted wall member 51 is disposed between first interlayer dielectric film 13 and second interlayer dielectric film 15. As a result, contact hole 21 is disposed in such a manner that the aperture width (W3) at the lower end is smaller than the aperture width (W2) at the upper end.

A contact plug 22 is disposed in contact hole 21 to be electrically connected to silicon film 12. An upper wiring layer 23 is disposed on second interlayer dielectric film 15 to be electrically connected to contact plug 22. Contact plug 22 has a shape corresponding to the shape of contact hole 21, and is disposed in such a manner that the lower end 22a has a smaller width than the upper end.

(Method of Producing the Semiconductor Device)

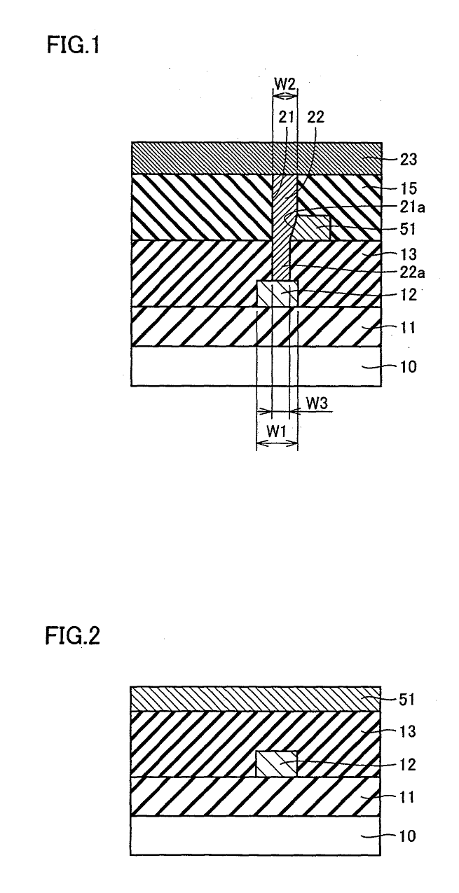

Next, a method of producing a semiconductor device having the aforesaid construction will be described referring to FIGS. 2 to 5. First, referring to FIG. 2, a silicon dielectric film 11 is formed on a semiconductor substrate 10, and a silicon film 12 is formed on this silicon dielectric film 11.

Silicon dielectric film 11 is constructed with a dielectric film such as TEOS oxide film or nitride film deposited by the reduced-pressure CVD (chemical vapor deposition) method or the ordinary-pressure CVD method, or with a laminate film thereof Silicon dielectric film 11 has a film thickness of from about 50 nm to about 1000 nm.

Silicon film 12 is constructed with polycrystalline silicon, amorphous silicon, or the like formed by the CVD method and doped with an impurity such as P or As, a silicide film of a high-melting-point metal film such as Ti, TiN, or W, or a laminate film thereof, or an electrically conductive metal film such as W or Al. Silicon film 12 has a film thickness of from about 50 nm to 500 nm.

Next, with the use of a photoresist having a predetermined pattern as a mask, silicon film 12 is etched by means of dry etching such as the RIE method to form a bitline 12 having a predetermined shape. Bitline 12 has a width (See FIG. 1) of from about 0.2 μm to about 1.0 μm. Thereafter, a first interlayer dielectric film 13 such as TEOS oxide film is formed to cover bitline 12. Subsequently, an etching control film 51 is deposited on first interlayer dielectric film 13. First interlayer dielectric film 13 is a dielectric film such as TEOS oxide film deposited by means of the reduced-pressure CVD method or the ordinary-pressure CVD method, and has a film thickness of from about 100 nm to about 300 nm. Etching control film 51 is a film constructed with polycrystalline silicon, amorphous silicon, or the like deposited by the CVD method and doped with an impurity such as P or As, a silicide film of a high-melting-point metal film such as Ti, TiN, or W, or a laminate film thereof, or an electrically conductive metal film such as W or Al, and has a film thickness of from about 50 nm to 500 nm.

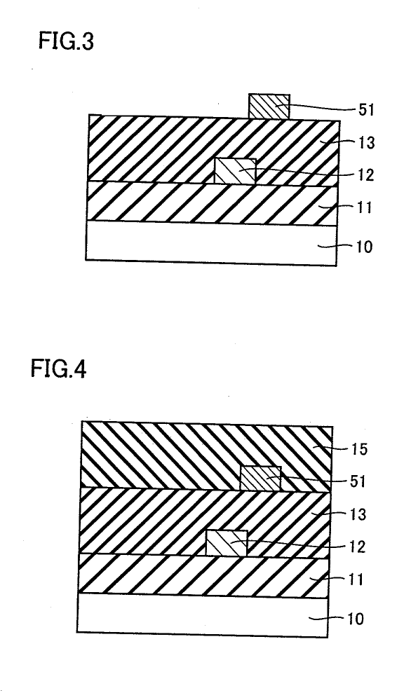

Next, referring to FIG. 3, with the use of a photoresist having a predetermined pattern as a mask, etching control film 51 is etched by means of dry etching such as the RIE method to complete an etching control member 51 having a predetermined shape. As illustrated, etching control member 51 is formed to overlap one side of the edge of bitline 12. Thereafter, referring to FIG. 4, a second interlayer dielectric film 15 is deposited to cover first interlayer dielectric film 13 and etching control member 51. Second interlayer dielectric film 15 is a dielectric film such as TEOS oxide film deposited by means of the reduced-pressure CVD method or the ordinary-pressure CVD method, and has a film thickness of from about 100 nm to about 3000 nm.

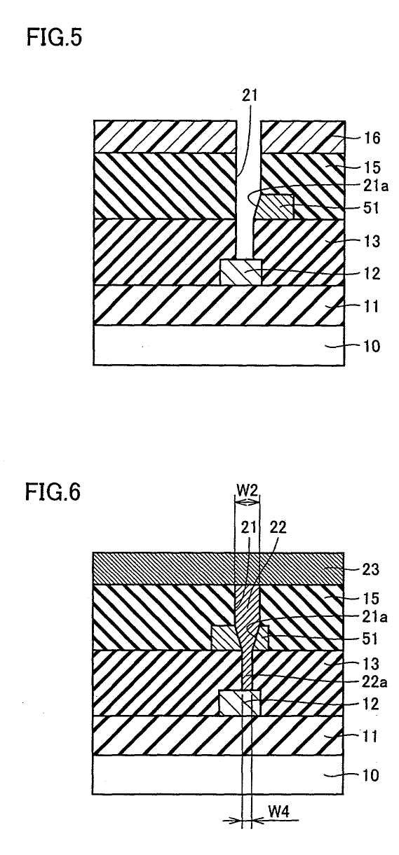

Next, referring to FIG. 5, with the use of a photoresist 16 having a predetermined pattern as a mask, a contact hole 21 that extends to bitline 12 is opened through first interlayer dielectric film 13 and second interlayer dielectric film 15 by means of dry etching such as the RIE method. Here, since etching control member 51 is made of a material having a lower etching rate than second interlayer dielectric film 15 with respect to an etchant (for example, a mixture gas of C4F8, O₂, and Ar) used in forming contact hole 21, etching control member 51 is etched to form a tilted wall 21a that gradually reduces the aperture width of contact hole 21 in a downward direction. As a result of this, the aperture width of contact hole 21 of first interlayer dielectric film 13 located below tilted wall member 51 made of this etching control member 51 is smaller than the aperture width of contact hole 21 of second interlayer dielectric film 15 located above tilted wall member 51. In this embodiment (See FIG. 1), the upper side of contact hole 21 has an aperture width (W2) of from about 0.2 μm to about 1.0 μm, and the lower side of contact hole 21 has an aperture width (W3) of from about 0.1 μm to about 0.8 μm.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 1.

(Functions and Effects)

As described above, according to the semiconductor device and method of producing the same in this embodiment, since a tilted wall member made of an etching control member is provided, the aperture width of the contact hole located below the etching control member can be reduced. As a result of this, one can form a contact hole having an aperture width smaller than the resolution limit of photolithography technique, whereby the overlap margin between contact hole 21 and bitline 12 can be improved.

(Second Embodiment)

Hereafter, referring to FIGS. 6 to 10, a semiconductor device and a method of producing the same according to a second embodiment will be described. Here, parts identical to or corresponding to those of the aforesaid first embodiment are denoted with the same reference numerals, and a detailed explanation thereof is omitted, so that only the characteristic features of this embodiment will be described.

(Structure of Semiconductor Device)

First, referring to FIG. 6, the characteristic structure of a semiconductor device according to this embodiment lies in that contact hole 21 is disposed to penetrate through tilted wall member 51 and, as a result of this, tilted wall 21a having a funnel shape is disposed over the entire surface of the inner circumferential wall of contact hole 21 that penetrates through tilted wall member 51. As a result of this, while the aperture width (W2) of contact hole 21 at the upper end is from about 0.2 μm to about 1.0 μm, the aperture width (W4) of contact hole 21 at the lower end can be reduced to about 0.05 μm to about 0.7 μm.

(Method of Producing the Semiconductor Device)

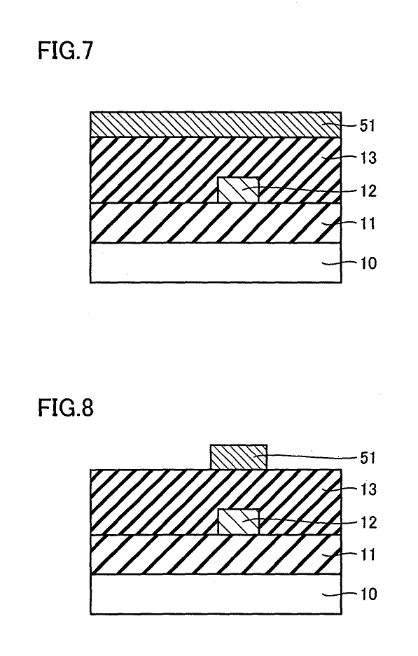

Next, a method of producing a semiconductor device having the aforesaid construction will be described referring to FIGS. 7 to 10. First, referring to FIG. 7, a silicon dielectric film 11 is formed on a semiconductor substrate 10, and a bitline 12 having a predetermined pattern shape is formed on this silicon dielectric film 11 in the same manner as in the aforesaid first embodiment. Thereafter, a first interlayer dielectric film 13 is formed to cover bitline 12. Subsequently, an etching control film 51 is deposited on first interlayer dielectric film 13.

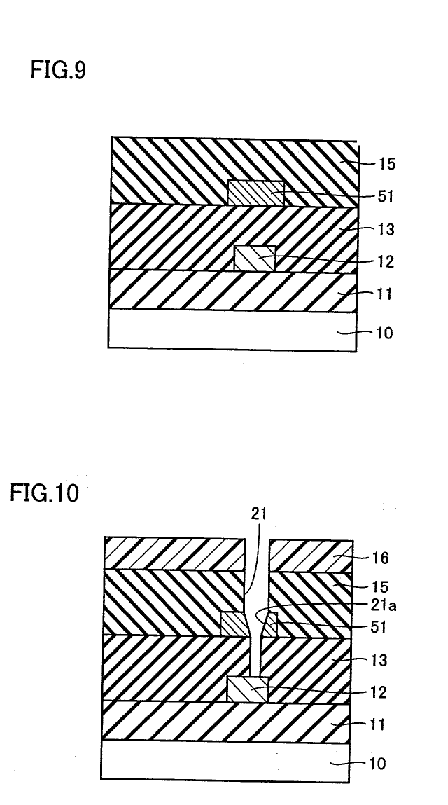

Next, referring to FIG. 8, with the use of a photoresist having a predetermined pattern as a mask, etching control film 51 is etched by means of dry etching such as the RIE method to complete an etching control member 51 having a predetermined shape. As illustrated, etching control member 51 is formed to completely overlap bitline 12 in this embodiment. Thereafter, referring to FIG. 9, a second interlayer dielectric film 15 is deposited to cover first interlayer dielectric film 13 and etching control member 51 in the same manner as in the first embodiment.

Next, referring to FIG. 10, with the use of a photoresist 16 having a predetermined pattern as a mask, a contact hole 21 that extends to bitline 12 is opened through first interlayer dielectric film 13 and second interlayer dielectric film 15 by means of dry etching such as the RIE method. Here, since etching control member 51 is made of a material having a lower etching rate than second interlayer dielectric film 15 with respect to an etchant used in forming contact hole 21 in the same manner as in the first embodiment, a tilted wall 21a having a funnel shape that gradually reduces the aperture width of contact hole 21 in a downward direction is formed to penetrate through etching control member 51. As a result of this, the aperture width of contact hole 21 of first interlayer dielectric film 13 located below tilted wall member 51 made of this etching control member 51 can be made smaller than the aperture width of contact hole 21 of second interlayer dielectric film 15 located above tilted wall member 51.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 6.

(Functions and Effects)

As described above, according to the semiconductor device and method of producing the same in this embodiment, functions and effects similar to those of the first embodiment can be obtained. Further, since a tilted wall 21a having a funnel shape that gradually reduces the aperture width of contact hole 21 in a downward direction is formed to penetrate through etching control member 51, the aperture width of contact hole 21 on the lower side can be further reduced, whereby the overlap margin between contact hole 21 and bitline 12 can be further improved.

(Third Embodiment)

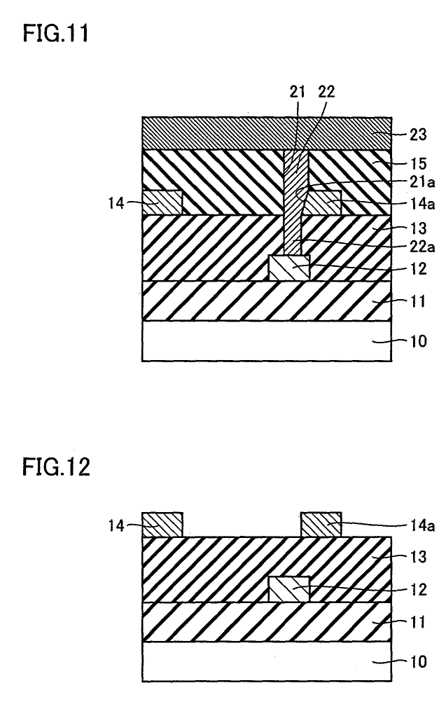

Hereafter, referring to FIGS. 11 to 14, a semiconductor device and a method of producing the same according to a third embodiment will be described. Here, parts identical to or corresponding to those of the aforesaid first embodiment are denoted with the same reference numerals, and a detailed explanation thereof is omitted, so that only the characteristic features of this embodiment will be described.

(Structure of Semiconductor Device)

First, referring to FIG. 11, the characteristic structure of a semiconductor device according to this embodiment is as follows. The basic feature lies in that the tilted wall member is made of a dummy cell plate 14a formed in the same step as a cell plate 14 that contributes to the operation of the semiconductor device. With respect to other features, the structure thereof is the same as that of the semiconductor device in the first embodiment.

(Method of Producing the Semiconductor Device)

Next, a method of producing a semiconductor device having the aforesaid construction will be described referring to FIGS. 12 to 14. First, referring to FIG. 12, a silicon dielectric film 11 is formed on a semiconductor substrate 10, and a bitline 12 having a predetermined pattern shape is formed on this silicon dielectric film 11 in the same manner as in the aforesaid first embodiment. Thereafter, a first interlayer dielectric film 13 is formed to cover bitline 12. Subsequently, a cell plate layer 14 that is to become a cell plate electrode later is deposited on first interlayer dielectric film 13. Cell plate layer 14 is constructed with polycrystalline silicon, amorphous silicon, or the like deposited by the CVD method and doped with an impurity such as P or As, a silicide film of a high-melting-point metal film such as Ti, TiN, or W, or a laminate film thereof, or an electrically conductive metal film such as W or Al, and has a film thickness of from about 50 nm to 500 nm.

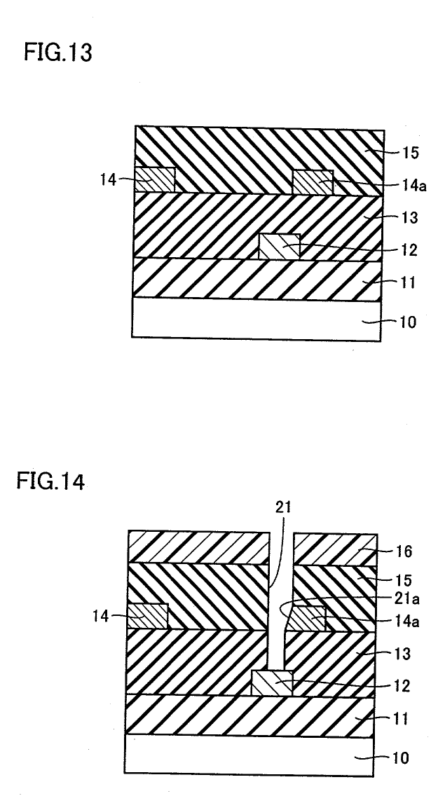

Next, with the use of a photoresist having a predetermined pattern as a mask, cell plate layer 14 is etched by means of dry etching such as the RIE method to form a cell plate 14 having a predetermined shape and, at the same time, to form a dummy cell plate 14a that overlaps one side of the edge of bitline 12. Thereafter, referring to FIG. 13, a second interlayer dielectric film 15 is deposited to cover first interlayer dielectric film 13 and etching control member 51 in the same manner as in the first embodiment.

Next, referring to FIG. 14, with the use of a photoresist 16 having a predetermined pattern as a mask, a contact hole 21 that extends to bitline 12 is opened through first interlayer dielectric film 13 and second interlayer dielectric film 15 by means of dry etching such as the RIE method. Here, since cell plate layer 14 is made of a material having a lower etching rate than second interlayer dielectric film 15 with respect to an etchant used in forming contact hole 21 in the same manner as in the first embodiment, dummy cell plate 14a serving as an etching control member is etched to form a tilted wall 21a that gradually reduces the aperture width of contact hole 21 in a downward direction. As a result of this, the aperture width of contact hole 21 of first interlayer dielectric film 13 located below this dummy cell plate 14a is smaller than the aperture width of contact hole 21 of second interlayer dielectric film 15 located above tilted wall member 51. The aperture width of contact hole 21 on the lower side and the aperture width of contact hole 21 on the upper side are the same as in the first embodiment.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 11.

(Functions and Effects)

As described above, according to the semiconductor device and method of producing the same in this embodiment, functions and effects similar to those of the first embodiment can be obtained. Further, since a dummy cell plate serving as a tilted wall member is formed at the same time in the cell plate forming step, there is no need to carry out a step of separately forming a tilted wall member, whereby the production process can be simplified.

(Fourth Embodiment)

Hereafter, referring to FIGS. 15 to 18, a semiconductor device and a method of producing the same according to a fourth embodiment will be described. Here, parts identical to or corresponding to those of the aforesaid first and second embodiments are denoted with the same reference numerals, and a detailed explanation thereof is omitted, so that only the characteristic features of this embodiment will be described.

(Structure of Semiconductor Device)

First, referring to FIG. 15, the characteristic structure of a semiconductor device according to this embodiment is as follows. The basic feature lies in that the tilted wall member is made of a dummy cell plate 14a formed in the same step as a cell plate 14 that contributes to the operation of the semiconductor device and that the contact hole 21 penetrates through dummy cell plate 14a. With respect to other features, the structure thereof is the same as that of the semiconductor device in the second embodiment.

(Method of Producing the Semiconductor Device)

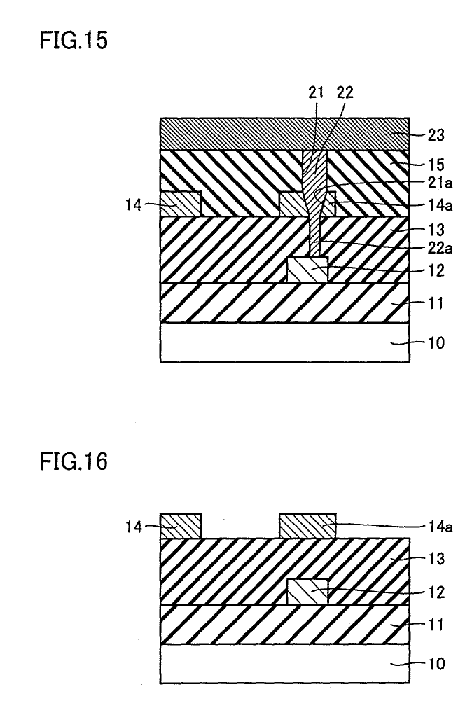

Next, a method of producing a semiconductor device having the aforesaid construction will be described referring to FIGS. 16 to 18. First, referring to FIG. 16, a silicon dielectric film 11 is formed on a semiconductor substrate 10, and a bitline 12 having a predetermined pattern shape is formed on this silicon dielectric film 11 in the same manner as in the aforesaid second embodiment. Thereafter, a first interlayer dielectric film 13 is formed to cover bitline 12. Subsequently, a cell plate layer 14 that is to become a cell plate electrode later is deposited on first interlayer dielectric film 13. Cell plate layer 14 is constructed with polycrystalline silicon, amorphous silicon, or the like deposited by the CVD method and doped with an impurity such as P or As, a silicide film of a high-melting-point metal film such as Ti, TiN, or W, or a laminate film thereof, or an electrically conductive metal film such as W or Al, and has a film thickness of from about 50 nm to 500 nm.

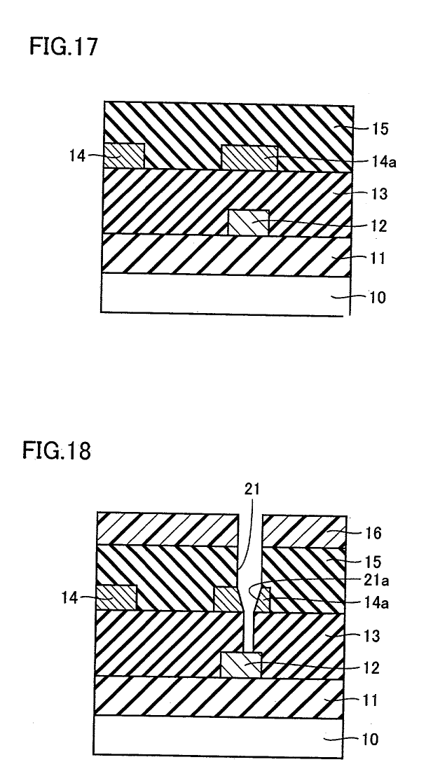

Next, with the use of a photoresist having a predetermined pattern as a mask, cell plate layer 14 is etched by means of dry etching such as the RIE method to form a cell plate 14 having a predetermined shape and, at the same time, to form a dummy cell plate 14a that completely overlaps bitline 12. Thereafter, referring to FIG. 17, a second interlayer dielectric film 15 is deposited to cover first interlayer dielectric film 13 and etching control member 51 in the same manner as in the first embodiment.

Next, referring to FIG. 18, with the use of a photoresist 16 having a predetermined pattern as a mask, a contact hole 21 that extends to bitline 12 is opened through first interlayer dielectric film 13 and second interlayer dielectric film 15 by means of dry etching such as the RIE method. Here, since cell plate layer 14 is made of a material having a lower etching rate than second interlayer dielectric film 15 with respect to an etchant used in forming contact hole 21 in the same manner as in the second embodiment, a tilted wall 21a having a funnel shape that gradually reduces the aperture width of contact hole 21 in a downward direction is formed to penetrate through cell plate layer 14. As a result of this, the aperture width of contact hole 21 of first interlayer dielectric film 13 located below this tilted wall member 51 made of etching control member 51 can be made smaller than the aperture width of contact hole 21 of second interlayer dielectric film 15 located above tilted wall member 51. The aperture width of contact hole 21 on the lower side and the aperture width of contact hole 21 on the upper side are the same as in the first embodiment.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 15.

(Functions and Effects)

As described above, according to the semiconductor device and method of producing the same in this embodiment, functions and effects similar to those of the second embodiment can be obtained. Further, since a dummy cell plate serving as a tilted wall member is formed at the same time in the cell plate forming step, there is no need to carry out a step of separately forming a tilted wall member, whereby the production process can be simplified.

(Fifth Embodiment)

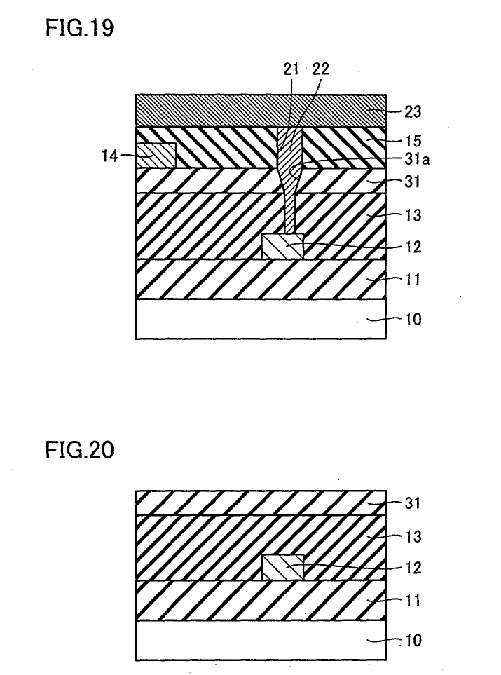

Hereafter, referring to FIGS. 19 to 23, a semiconductor device and a method of producing the same according to a fifth embodiment will be described. Here, parts identical to or corresponding to those of the aforesaid first embodiment are denoted with the same reference numerals, and a detailed explanation thereof is omitted, so that only the characteristic features of this embodiment will be described.

(Structure of Semiconductor Device)

First, referring to FIG. 19, the characteristic structure of a semiconductor device according to this embodiment lies in that a dielectric layer 31 is disposed between first interlayer dielectric film 13 and second interlayer dielectric film 15 as a tilted wall member. Further, contact hole 21 is disposed to penetrate through this dielectric layer 31. As a result of this, a tilted wall 31 a having a funnel shape is disposed over the entire surface of the inner circumferential wall of contact hole 21 that penetrates through dielectric layer 31. Here, the aperture width at the upper end of contact hole 21 and the aperture width at the lower end of contact hole 21 are set to be approximately the same as in the second embodiment.

(Method of Producing the Semiconductor Device)

Next, a method of producing a semiconductor device having the aforesaid construction will be described referring to FIGS. 20 to 23. First, referring to FIG. 20, a silicon dielectric film 11 is formed on a semiconductor substrate 10, and a bitline 12 having a predetermined pattern shape is formed on this silicon dielectric film 11 in the same manner as in the aforesaid first embodiment. Thereafter, a first interlayer dielectric film 13 is formed to cover bitline 12. Subsequently, a dielectric layer 31 is deposited on first interlayer dielectric film 13. Dielectric layer 31 is made of a nitride film or the like deposited by means of the reduced-pressure CVD or the ordinary-pressure CVD, and has a film thickness of from about 100 nm to about 3000 nm.

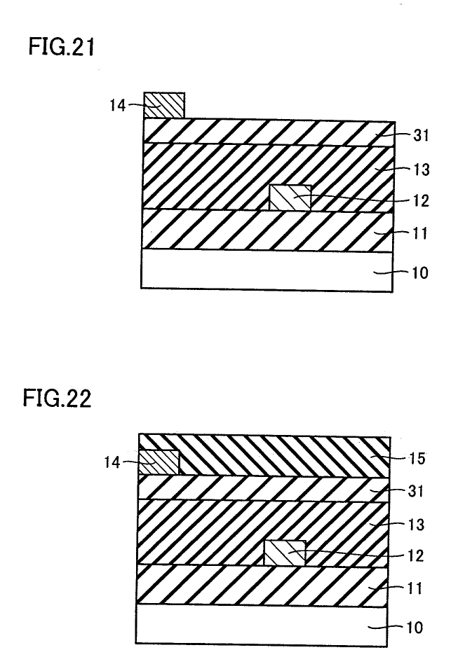

Next, referring to FIG. 21, a cell plate electrode 14 having a predetermined pattern shape is formed at a predetermined position of dielectric layer 31. Thereafter, referring to FIG. 22, a second interlayer dielectric film 15 is deposited to cover dielectric layer 31 and cell plate electrode 14.

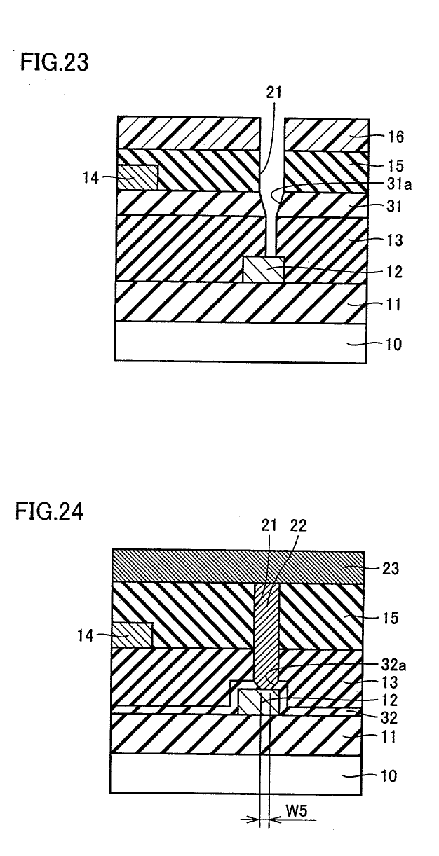

Next, referring to FIG. 23, with the use of a photoresist 16 having a predetermined pattern as a mask, a contact hole 21 that extends to bitline 12 is opened through first interlayer dielectric film 13, dielectric layer 31, and second interlayer dielectric film 15 by means of dry etching such as the RIE method. Here, since dielectric layer 31 is made of a material having a lower etching rate than second interlayer dielectric film 15 with respect to an etchant used in forming contact hole 21 in the same manner as in the first embodiment, a tilted wall 31a having a funnel shape that gradually reduces the aperture width of contact hole 21 in a downward direction is formed to penetrate through dielectric layer 31. As a result of this, the aperture width of contact hole 21 of first interlayer dielectric film 13 located below this dielectric layer 31 can be made smaller than the aperture width of contact hole 21 of second interlayer dielectric film 15 located above dielectric layer 31.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 19.

(Functions and Effects)

As described above, according to the semiconductor device and method of producing the same in this embodiment, functions and effects similar to those of the first embodiment can be obtained. Further, since tilted wall 31a having a funnel shape that gradually reduces the aperture width of contact hole 21 in a downward direction is formed to penetrate through dielectric layer 31, the aperture width of contact hole 21 on the lower side can be further reduced, whereby the overlap margin between contact hole 21 and bitline 12 can be further improved.

(Sixth Embodiment)

Hereafter, referring to FIGS. 24 to 27, a semiconductor device and a method of producing the same according to a sixth embodiment will be described. Here, parts identical to or corresponding to those of the aforesaid first embodiment are denoted with the same reference numerals, and a detailed explanation thereof is omitted, so that only the characteristic features of this embodiment will be described.

(Structure of Semiconductor Device)

First, referring to FIG. 24, the characteristic structure of a semiconductor device according to this embodiment is as follows. The basic feature lies in that a dielectric film 32 serving as a tilted wall member is disposed on bitline 12.

(Method of Producing the Semiconductor Device)

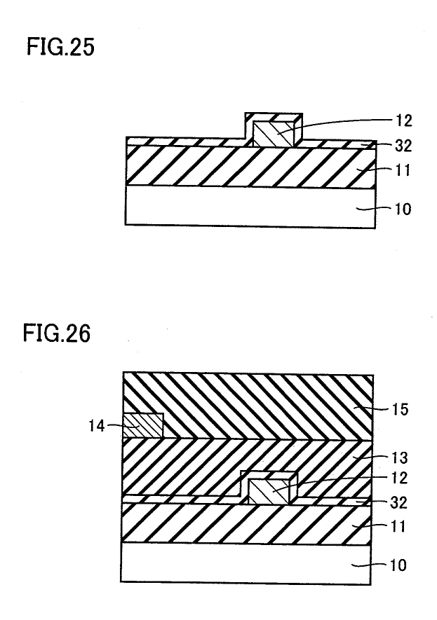

Next, a method of producing a semiconductor device having the aforesaid construction will be described referring to FIGS. 25 to 27. First, referring to FIG. 25, a silicon dielectric film 11 is formed on a semiconductor substrate 10, and a bitline 12 having a predetermined pattern shape is formed on this silicon dielectric film 11 in the same manner as in the aforesaid first embodiment. Thereafter, a dielectric film 32 is formed to cover bitline 12 and silicon dielectric film 11. Dielectric film 32 is made of a nitride film or the like deposited by means of the reduced-pressure CVD or the ordinary-pressure CVD, and has a film thickness of from about 100 nm to about 3000 nm.

Next, referring to FIG. 26, a first interlayer dielectric film 13 is formed on dielectric film 32. Thereafter, a cell plate electrode 14 having a predetermined shape is formed at a predetermined position on first interlayer dielectric film 13. Subsequently, a second interlayer dielectric film 15 is deposited to cover first interlayer dielectric film 13 and cell plate electrode 14.

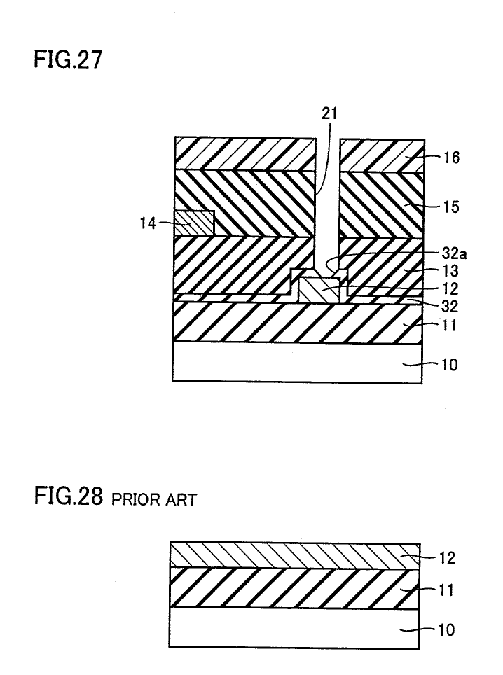

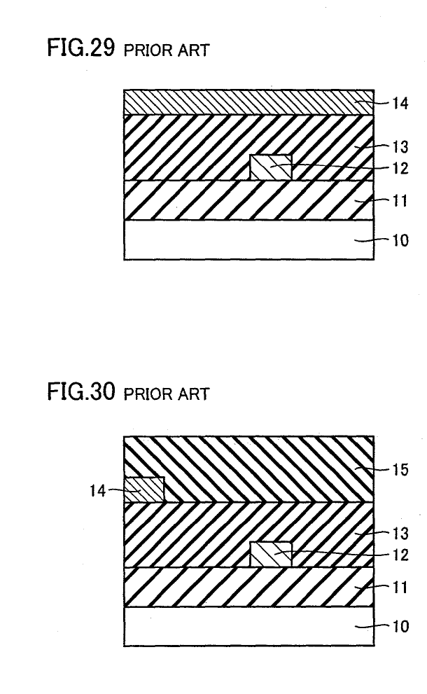

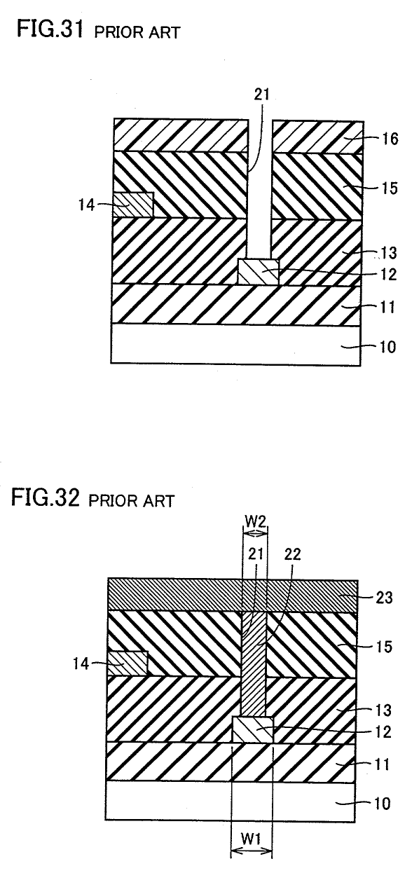

Next, referring to FIG. 27, with the use of a photoresist 16 having a predetermined pattern as a mask, a contact hole 21 that extends to bitline 12 is opened through first interlayer dielectric film 13, second interlayer dielectric film 15, and dielectric film 32 by means of dry etching such as the RIE method. Here, since dielectric film 32 is made of a material having a lower etching rate than first interlayer dielectric film 13 with respect to an etchant used in forming contact hole 21 in the same manner as in the first embodiment, a tilted wall 32a having a funnel shape that gradually reduces the aperture width of contact hole 21 in a downward direction is formed through dielectric film 32 serving as an etching control member. As a result of this, the aperture width of contact hole 21 at the bottom of this dielectric film 32 is smaller than the aperture width of contact hole 21 above dielectric film 32. The aperture width W5 of contact hole 21 at the bottom of dielectric film 32 (See FIG. 24) is from about 0.05 μm to about 0.7 μm.

Next, after resist film 16 is removed, a contact plug 22 is formed within contact hole 21. Thereafter, an upper wiring layer 23 electrically connected to contact plug 22 is formed on silicon dielectric film 15. This completes the semiconductor device shown in FIG. 24.

(Functions and Effects)

As described above, according to the semiconductor device and method of producing the same in this embodiment, functions and effects similar to those of the first embodiment can be obtained.

According to the semiconductor devices and methods of producing the same provided by the present invention, the aperture width on the lower end side of the contact hole can be reduced, whereby the overlap margin between the contact hole and the bitline can be improved, and the pitch of the bitline can be reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a lower wiring layer;
an interlayer dielectric film disposed on said lower wiring layer;
an upper wiring layer disposed on said interlayer dielectric film;
a contact hole disposed through said interlayer dielectric film to couple said lower wiring layer and said upper wiring layer with each other; and
a contact plug buried in said contact hole to establish an electrical connection between said lower wiring layer and said upper wiring layer,
wherein a tilted wall member is disposed on an inner wall surface of said contact hole for gradually reducing an aperture width of said contact hole in a downward direction.

2. The semiconductor device according to claim 1, wherein
said interlayer dielectric film has a first interlayer dielectric film located on a lower side and a second interlayer dielectric film disposed above said first interlayer dielectric film, and
said tilted wall member is disposed between said first interlayer dielectric film and said second interlayer dielectric film.

3. The semiconductor device according to claim 1, wherein said contact hole is disposed to penetrate through said tilted wall member.

4. The semiconductor device according to claim 1, wherein said tilted wall member is a dummy cell plate electrode.

5. The semiconductor device according to claim 1, wherein said tilted wall member is disposed between said interlayer dielectric film and said lower wiring layer.

6. The semiconductor device according to claim 5, wherein said contact hole is disposed to penetrate through said tilted wall member.

7. A method of producing a semiconductor device comprising the steps of:
forming a lower wiring layer;
forming a first interlayer dielectric film on said lower wiring layer;
forming an etching control member having a predetermined shape on said first interlayer dielectric film;
forming a second interlayer dielectric film on said first interlayer dielectric film and said etching control member;
forming a contact hole by etching so that said contact hole may pass said etching control member to reach said lower wiring layer;
forming a contact plug in said contact hole so that said contact plug may be electrically connected to said lower wiring layer; and
forming an upper wiring layer on said second interlayer dielectric film so that said upper wiring layer may be electrically connected to said contact plug,
wherein said etching control member is made of a material having a lower etching rate than said second interlayer dielectric film with respect to an etchant used in forming said contact hole.

8. The method of producing a semiconductor device according to claim 7, wherein the step of forming said contact hole is carried out so that said contact hole may penetrate through said etching control member.

9. The method of producing a semiconductor device according to claim 7, further comprising the step of forming a cell plate electrode between said first interlayer dielectric film and said second interlayer dielectric film, wherein the step of forming said etching control member is carried out so that said etching control member may be formed in the same step and with the same material as in the step of forming said cell plate electrode.

10. A method of producing a semiconductor device comprising the steps of:
forming a lower wiring layer;
forming an etching control member on said lower wiring layer;
forming an interlayer dielectric film on said etching control member;
forming a contact hole by etching so that said contact hole may pass said etching control member to reach said lower wiring layer;
forming a contact plug in said contact hole so that said contact plug may be electrically connected to said lower wiring layer; and
forming an upper wiring layer on said interlayer dielectric film so that said upper wiring layer may be electrically connected to said contact plug,
wherein said etching control member is made of a material having a lower etching rate than said interlayer dielectric film with respect to an etchant used in forming said contact hole.

11. The method of producing a semiconductor device according to claim 10, wherein the step of forming said contact hole is carried out so that said contact hole may penetrate through said etching control member.
